(19) United States
(12) Patent Application Publication
(10) Pub. No.: US 2025/0132284 A1
(43) Pub. Date: Apr. 24, 2025

(54) DIE BONDING TOOL WITH TILTABLE BOND STAGE AND METHODS FOR PERFORMING THE SAME

(71) Applicant: TAIWAN SEMICONDUCTOR MANUFACTURING COMPANY, LTD., Hsinchu (TW)

(72) Inventors: Amram EITAN, Hsinchu (TW); Hui-Ting LIN, Tainan (TW); Chih-Yuan CHIU, Hsinchu (TW); Kai Jun ZHAN, Taoyuan (TW); Yi Chen WU, Taichung (TW)

(21) Appl. No.: 18/492,777

(22) Filed: Oct. 24, 2023

(51) Int. Cl. H01L 23/00

(52) U.S. Cl. CPC H01L 24/75; H01L 24/81; H01L 2224/75804; H01L 2224/81801

(57) ABSTRACT

Embodiments of the present disclosure provide a bond stage for bonding a semiconductor integrated circuit (IC) die. The bond stage includes a bonding platform having a top surface and a bottom surface opposing the top surface, a first actuator operable to tilt the bonding platform about a first rotation axis, and a plurality of contact sensors disposed at the bonding platform.

### BACKGROUND

The semiconductor industry has grown due to continuous improvements in integration density of various electronic components (e.g., transistors, diodes, resistors, capacitors, etc.). For the most part, these improvements in integration density have come from successive reductions in minimum feature size, which allows more components to be integrated into a given area.

In addition to smaller electronic components, improvements to the packaging of components have been developed in an effort to provide smaller packages that occupy less area than previous packages. Three-dimensional devices, such as three-dimensional integrated circuits (3DICs), System on Chip (SoC), or integrated SoC devices are prepared by placing chips over chips on a semiconductor wafer level. These three-dimensional devices provide improved integration density and other advantages, such as faster speeds and higher bandwidth, because of the decreased length of interconnects between the stacked chips. However, there are challenges related to three-dimensional devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic view of a die bonding tool in accordance with various embodiments of the present disclosure.

FIG. 2 is a vertical cross-sectional view of a bond head assembly of the die bonding tool according to various embodiments of the present disclosure.

FIG. 3A is a vertical cross-sectional view of a bond stage according to various embodiments of the present disclosure.

FIG. 3B is a bottom view of the bond stage of FIG. 3A illustrating a plurality of contact sensors according to various embodiments of the present disclosure.

FIGS. 4A and 4B are vertical cross-sectional views of the die bonding tool of FIG. 3A illustrating a tilt motion of the bond stage according to various embodiments of the present disclosure.

FIGS. 5A-5E are sequential vertical cross-sectional views illustrating a process of bonding a semiconductor IC die to a target substrate using a die bonding tool according to various embodiments of the present disclosure.

FIGS. 6A-6E are sequential vertical cross-section views illustrating an alternative process of bonding a semiconductor IC die to a target substrate using the die bonding tool according to various embodiments of the present disclosure.

FIG. 7 is a flowchart illustrating a method of bonding a semiconductor IC die to a target substrate using a die bonding tool, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, a die bonding tool may be used to bond a semiconductor integrated circuit (IC) die (which may also be referred to as a “chip”) to a target substrate, such as a semiconductor wafer. The die bonding tool may include a bond head that is configured to temporarily adhere a semiconductor IC die to the bond head, such as via a vacuum suction force. The die bonding tool may also include a bond stage on which the target substrate is placed. The die bonding tool may align the semiconductor IC die over a bonding region of the target substrate and bring bonding structures, such as metal bonding pads, metal pillars, and/or solder material portions, on the lower surface of the semiconductor IC die into contact with corresponding bonding structures on the upper surface of the target substrate. The bond head may then be used to apply a compressive force to the semiconductor IC die to bond the semiconductor IC die to the bonding region of the target substrate.

To form an effective bond between the semiconductor IC die and the target substrate, it is desirable to form good contact between the bonding structures on the semiconductor IC die and the corresponding bonding structures on the target substrate. For larger semiconductor package sizes with a small pitch between adjacent bonding structures, the process window for providing an effective bond between the semiconductor IC die and the target substrate becomes increasingly sensitive to variations in the thickness and/or surface planarity of the target substrate and the semiconductor IC die. In embodiments in which the interfacing bonding surfaces on the target substrate and/or the semiconductor IC die are not perfectly parallel to the surface of the bond head to which the semiconductor IC die is affixed, there may be differences in the vertical height of the bonds that occur between the semiconductor IC die and the target substrate across different regions of the semiconductor IC die. A large variation in joint heights may result in poor or defective bonding between the semiconductor IC die and the target substrate, which may negatively impact device performance and yields.

In order to improve the bonding between a semiconductor IC die and a target substrate, various embodiments of the present disclosure are directed to a die bonding tool that includes a tiltable bond stage on which the target substrate is placed, a bond head having a planar surface to which the semiconductor IC die may be secured, and a plurality of contact sensors. The bond stage is tiltable about at least one tilt axis. In various embodiments, a first actuator may move the bond head and the semiconductor die towards a surface of a target substrate disposed on the tiltable bond stage, a second actuator may move and/or tilt the bond stage when an initial contact between a first region of the semiconductor die and the surface of the target substrate is detected. In response to detecting the initial contact between the semiconductor die and the first region of the target substrate, the second actuator may be configured to tilt the bond stage (and therefore the target substrate) to bring a second region of the target substrate into contact with the surface of the semiconductor die. Accordingly, improved contact may be achieved between the semiconductor die and the target substrate in instances in which at least one of the interfacing surfaces between the semiconductor IC die and the target substrate are not parallel to the planar surface of the bond head. Compared to traditional approach in which the bond stage is checked and kept flat during the tool step, and use pre-known angle to perform the bonding process, the inventive approach use the bond stage with a self-tilting feature to adjust the angle when bonding. As a result, the inventive approach can result in more effective bonding with reduced joint height variation in the bonds formed between the semiconductor IC die and the target substrate.

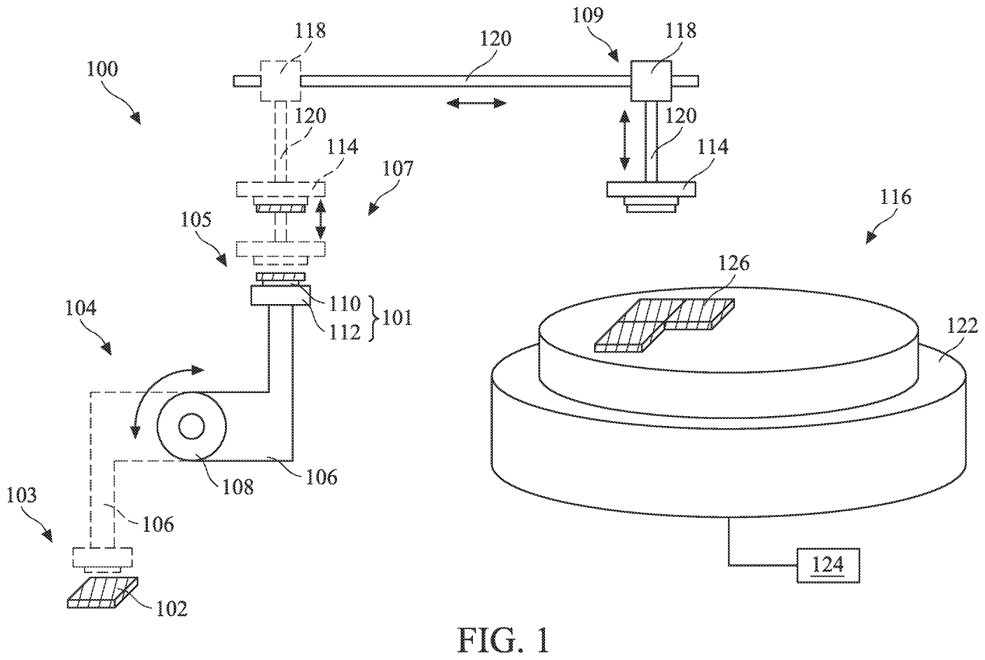

FIG. 1 illustrates a schematic view of a die bonding tool 100 in accordance with various embodiments of the present disclosure. The die bonding tool 100 may be used during the manufacturing of integrated circuits, which often involves bonding of semiconductor IC dies to processed wafers, such as a target substrate 116. In a typical die bonding process, a semiconductor IC die 102 is first picked up by a flipper 104, and then transported to one or more bond head assemblies 114 (only one is shown). The flipper 104 is operable to pick up semiconductor IC dies one-by-one from a wafer (not shown) that has already been sawed into dies. While not shown, the flipper 104 is configurable to perform movements in at least one horizontal direction (x-direction) and in the vertical direction (z-direction). The wafer may be a device wafer, and the semiconductor IC die 102 may include integrated circuit devices (such as transistors) therein.

The flipper 104 has an arm 106 coupled to an actuator 108. The actuator 108 may rotate the arm 106 about the axis of the actuator 108 and move the arm 106 back and forth between a first position 103 (where the semiconductor IC die 102 is picked up) and a second position 105 (where the semiconductor IC die 102 is released). A vacuum tip assembly 101 is removably coupled to the arm 106 of the flipper 104. The vacuum tip assembly 101 generally includes a vacuum tip 110 and a mounting support 112. Application of a vacuum produced by a vacuum pump (not shown) causes the vacuum tip 110 to pick up the semiconductor IC die 102. The flipper 104 shown in dotted lines illustrates the position of the arm 106 and the flipper 104 for picking up the semiconductor IC die 102, while the flipper 104 in solid lines illustrate the position of the same flipper 104 for releasing flipped semiconductor IC die 102.

The bond head assemblies 114 are vertically movable with respect to the flipper 104 and are used to move the semiconductor IC die 102 from the flipper 104 to the target substrate 116. The target substrate 116 may have a plurality of integrated circuit dies (e.g., die 126) disposed thereon. If desired, the target substrate 116 may be replaced with a carrier wafer. The bond head assembly 114 may be a vacuum head capable of picking up die (e.g., the semiconductor IC die 102) through vacuum force. The bond head assembly 114 may be coupled to a moving member 118 through a stem 120. The moving member 118 is operable to move the bond head assembly 114 towards the flipper 104 and pick up the flipped semiconductor IC die 102 from the flipper 104. The moving member 118 can move the bond head assembly 114 along a guide rail 120 between a third position 107 (where the flipped device die is released from the flipper 104) and a fourth position 109 directly above the target substrate 116. The target substrate 116 may be disposed on a bond stage 122. The bond stage 122 may be connected to a heater 124, which imparts local heating to the target substrate 116. A control unit (not shown) may be electrically connected to the flipper 104, the bond head assembly 114, the moving member 118, the bond stage 122, and the heater 124 so that actions of the bond stage, 122, the bond head assembly 114, and the flipper 104 may be controlled and synchronized with the movement of the semiconductor IC die 102 and the target substrate 116.

In operation, the flipper 104 is directed to move the arm 106 to the first position 103 where dies are to be picked up from a wafer (not shown). The wafer may be moved in the X and Y directions so that each one of dies (e.g., the semiconductor IC die 102) on the wafer is moved to directly under the flipper 104 one at a time. The flipper 104 may flip and/or move the arm 106 through the actuator 108 so that the vacuum tip 110 is facing the front side of the semiconductor IC die 102. Then, the flipper 104 moves towards and contacts the semiconductor IC die 102 with the vacuum tip 110. Once the semiconductor IC die 102 is secured to the vacuum tip 110, the flipper 104 moves backwards and the arm 106 may be flipped or moved again, with the backside of the picked-up semiconductor IC die 102 facing up, from the first position 103 to the second position 105. Next, the moving member 118 moves the bond head assembly 114 towards the flipped semiconductor IC die 102 and contacts the backside of the flipped semiconductor IC die 102. Once the flipped semiconductor IC die 102 is secured to the bond head assembly 114, vacuum applied to the front side of the semiconductor IC die 102 (by the flipper 104) is turned off, and the moving member 118 moves the bond head assembly 114 backwards, with the front side of the semiconductor IC die 102 facing down.

The moving member 118 moves the bond head assembly 114 from the third position 107 to the fourth position 109, where the semiconductor IC die 102 is to be placed on the target substrate 116. In the meantime, the flipper 104 may continue to pick up dies from the wafer in a similar fashion as discussed above. The moving member 118 moves the bond head assembly 114 (carrying the semiconductor IC die 102) downwardly towards dies (e.g., die 126) on the target substrate 116. As mentioned earlier and will be discussed in more detail below, the bond head assembly 114 and/or the bond stage 122 are tiltable to improve contact between the semiconductor IC die and the target substrate. After a plurality of semiconductor IC dies are placed on the target substrate 116, a thermal process may be performed (by the heater 124) so that the device dies (e.g., semiconductor IC die 102) are bonded to the corresponding die (e.g., die 126) on the target substrate 116. The dies may be bonded together through fusion or hybrid bonding technologies, such as an insulator-to-insulator, a metal-to-metal, or an insulator-to-metal bonding process. The dies can be bonded face-to-face (F2F) or face-to-back (F2B). In a F2F bonding configuration the active surfaces of the dies are bonded together, whereas in a F2B bonding configuration, an active surface of one die is bonded to a back surface of another die. After completion of bonding, the bond head assembly 114 is moved away from the target substrate 116 by the moving member 118, and the moving member 118 moves the bond head assembly 114 back to the third position 107 to pick up another die from the flipper 104.

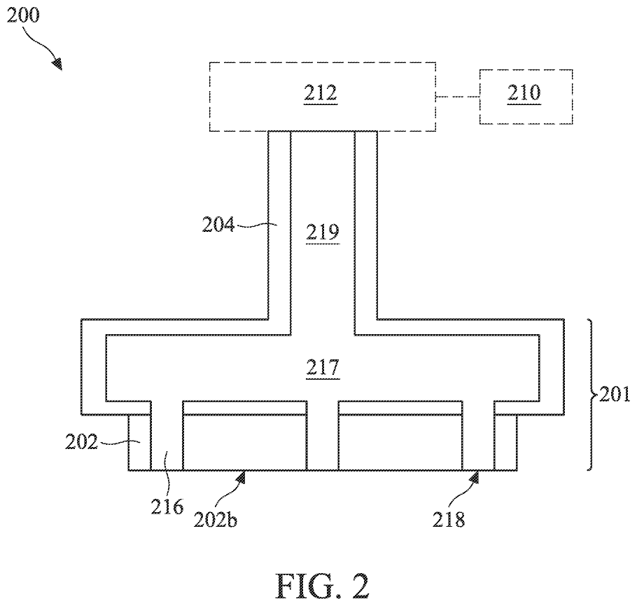

FIG. 2 is a vertical cross-sectional view of a bond head assembly 200 of the die bonding tool 100 according to various embodiments of the present disclosure. The bond head assembly 200 may include an actuator 212 configured to move the bond head 201, and a connecting member 204 extending between the actuator 212 and the bond head 201. The bond head 201 may include a nozzle plate 202 having a substantially flat lower surface 202b. The nozzle plate 202 of the bond head 201 may also include one or more openings 218 (i.e., ports) in the lower surface 202b of the nozzle plate 202. In some embodiments, one or more fluid conduits 216 in the bond head 201 may extend between each opening 218 in the lower surface 202b of the nozzle plate 202 and an internal plenum 217 of the tool head 201. A fluid conduit 219 may extend through the connecting member 204 to couple the internal plenum 217 of the tool head 201 to a vacuum source (not shown). The vacuum source may selectively apply a negative pressure within the fluid conduit 219, the plenum 217 and the fluid conduit(s) 216 such that a vacuum or suction force may be generated at each of the openings 218 in the nozzle plate 202. The suction force may be sufficient to secure a semiconductor IC die against the lower surface 202b of the nozzle plate 202.

The bond head assembly 200 may include a system controller 210, which may be central processing unit (CPU), that may be operatively coupled to the actuator 212. The system controller 210 may be configured to send control signals the actuator 212 to cause actuator 212 to move the bond head 201 and connecting member 204. In various embodiments, the actuator 212 may be configured to translate the bond head 201 and connecting member 204 along horizontal and/or vertical directions. In some cases, the actuator 212 may also be configured to tilt the bond head 201. In some embodiments, the system controller 210 may also control the operation of the vacuum source to selectively provide a suction force at each of the openings 218 in the nozzle plate 202.

FIG. 2A is a vertical cross-sectional view of a bond stage 300 of the die bonding tool 100 of FIG. 1, in accordance with some embodiments of the present disclosure. The bond stage 300 may include a bonding platform 302, a plurality of actuators 312a-312d (collectively referred to as 312) configured to move the bonding platform 302, a plurality of contact sensors 311a-311d (collectively referred to as 311) mounted to the bonding platform 302, and a system controller 310 operatively coupled to the actuators 312 and the contact sensors 311. The bonding platform 302 has a top surface 302t for supporting the target substrate (not shown, such as the target substrate 116). The bonding platform 302 includes a plurality of small holes or perforations 303 (four holes are shown) extending through the body of the bonding platform 302. Each hole 303 has an opening 318 (i.e., ports) in the top surface 302t of the bonding platform 302. The one or more holes or perforations 303 in bonding platform 302 may extend between the opening 318 in the top surface 302t of the bonding platform 302 and an internal plenum 317 of the bonding platform 302. A fluid conduit 319 may extend within the bonding platform 302 to fluidly couple the internal plenum 317 to a vacuum source (not shown). The vacuum source is used to secure the target substrate against the top surface 302t by selectively applying a negative pressure to the small holes or perforations 303. The negative pressure is sufficient such that a vacuum or suction force is generated at each of the openings 318. The vacuum or suction force is applied to a back surface (e.g., non-bonding surface) of the target substrate disposed on the top surface 302t of the bonding platform 302, allowing the target substrate to secure and conform to the top surface 302t of the bonding platform 302.

The system controller 310 may be the same as the system controller 210. Alternatively, the bond stage 300 may be controlled by the system controller 210. In either case, the system controller 210, 310 is configured to send control signals, in response to the information received from the contact sensors 311, to the actuator 312 to cause the actuators 312 to move the bond stage 300. The system controller 310 may also control the operation of the vacuum source to selectively provide a suction force at each of the openings 318 in the bonding platform 302. The actuators 312 may be disposed at a bottom surface 302b of the bond stage 300. The number of the actuators 312 may range between 2 and 12, such as about 4 and 8. However, greater or less actuators 312 may be used. In some embodiments, the actuators 312a, 312b, 312c, 312d are equally spaced apart along the circumference of the bond stage 300 (or symmetrically arranged with respect to a vertical line extending through a center point 333 of the bonding platform 302). In various embodiments, the actuators 312 are configured to translate the bond stage 300 along horizontal and/or vertical directions, as well as to tilt the bond stage 300 with respect to the bond head assembly 200, as will be described in further detail below.

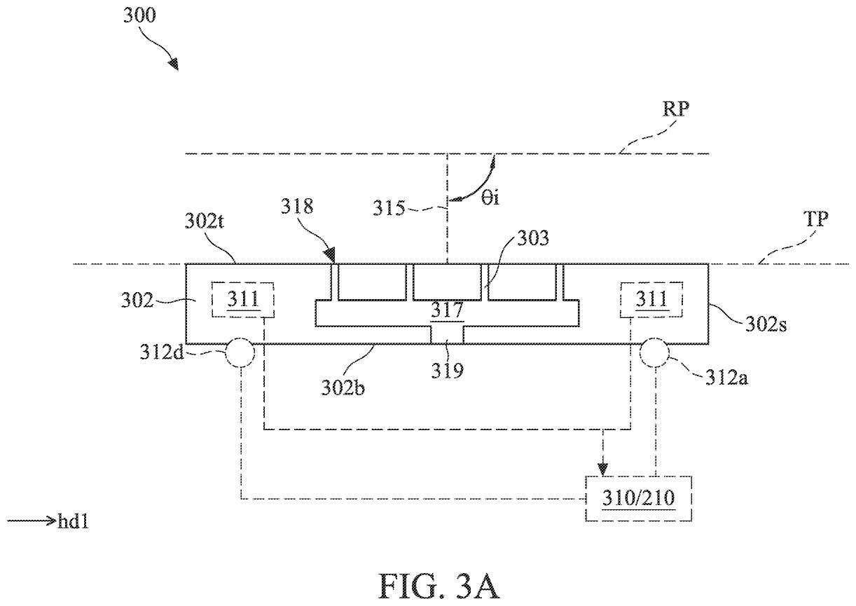

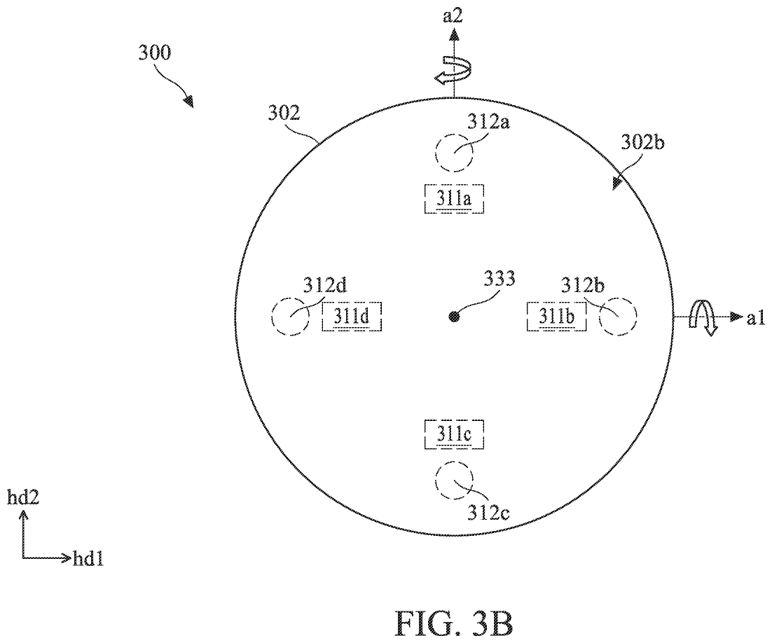

The contact sensors 311 are configured to detect initial contact between an object, such as a semiconductor IC die on the bond head 201, and a target substrate on the bond stage 300 to which the semiconductor IC die is to be bonded. Such information can be used to assist the system controller 310 in calculating and adjusting the degree of tilting for the bond stage 300. The contact sensors 311 may be disposed in and/or on the bonding platform 302 of the bond stage 300. Each of the contact sensors 311 may be operatively coupled to the system controller 310 (or the system controller 210) as schematically indicated by dashed lines in FIG. 3A. FIG. 3B is a bottom view of the bond stage 300 of FIG. 3A illustrating a plurality of contact sensors 311 according to various embodiments of the present disclosure. Although FIGS. 3A and 3B illustrate the contact sensors 311 located in the bonding platform 302, it will be understood that in other embodiments, contact sensors 311 may located in another location on the bond stage 300, such as on the top surface 302t or sidewall 302s of the bonding platform 302. Additionally or alternatively, the contact sensors 311 may be located at the bond head 201 and/or the connecting member 204.

In various embodiments, the contact sensors 311 may be configured to detect contact with the bond stage 300 and/or the integrated circuit die (e.g., die 126) at different regions of the target substrate. In the embodiment shown in FIG. 3B, four contact sensors 311 are configured to detect contact at outer peripheral regions of the bonding platform 302 and/or target substrate. It will be understood that other embodiments may include a greater or less number of contact sensors 311 for detecting contact in different regions of the bond stage 300 and/or the target substrate. If multiple contact sensors 311 are used, the contact sensors 311 may be symmetrically arranged with respect to a vertical line extending through the center point 333 of the bonding platform 302. Furthermore, although FIGS. 3A and 3B illustrate a bond stage 300 that is cylindrical in shape (i.e., circular shape), the bond stage 300 may have a quadrilateral shape or oval shape, and may include contact sensors 311 for detecting contact in different regions, such as around the outer periphery of the bond stage 300.

In some embodiments, at least one contact sensor 311 may include a plurality of force sensors located in different regions of the bond stage 300. The force sensors may be configured to detect a force applied to the bond stage 300 and/or the target substrate disposed thereon indicating that a particular region of the bond stage 300 and/or the integrated circuit die (e.g., die 126) at that particular region of the target substrate has contacted another object, such as a semiconductor IC die on the bond head. Suitable examples of force sensors may include, without limitation, strain gauges, load cells, force sensing resistors, and the like. Other suitable force sensors are within the contemplated scope of disclosure. Alternatively, or additionally, the at least one contact sensor 311 may include other types of feedback sensors, such as one or more encoders that are configured to determine the relative position and/or motion of different regions of the bond stage 300, where a change in the relative position and/or motion of a particular region of the bond stage 300 may indicate that the region of the bond stage 300 and/or the integrated circuit die (e.g., die 126) has contacted another object, such as a semiconductor IC die on the bond head. Other suitable contact sensors 311 are within the contemplated scope of disclosure.

Referring again to FIG. 3A, in various embodiments, the top surface 302t of the bonding platform 302 of the bond stage 300 may have an initial orientation with respect to a reference plane RP. In the embodiment shown in FIG. 3A, the reference plane RP is a horizontal plane that is parallel to a first horizontal direction hd1, although it will be understood that the reference plane RP may not be a horizontal plane. The flat top surface 302t of the bonding platform 302 may define a tool plane TP that may have an initial orientation with respect to the reference plane RP. In the embodiment of FIG. 3A, the tool plane TP defined by the top surface 302t of the bonding platform 302 is parallel to the reference plane RP such that a line 315 normal to the top surface 302t of the bonding platform 302 is perpendicular to the reference plane RP. That is, the angle θi between line 315 and the reference plane RP is 90°. It will be understood in other embodiments, the initial orientation of the bond stage 300 may define a tool plane TP that is not parallel to the reference plane RP (i.e., θi≠90°.

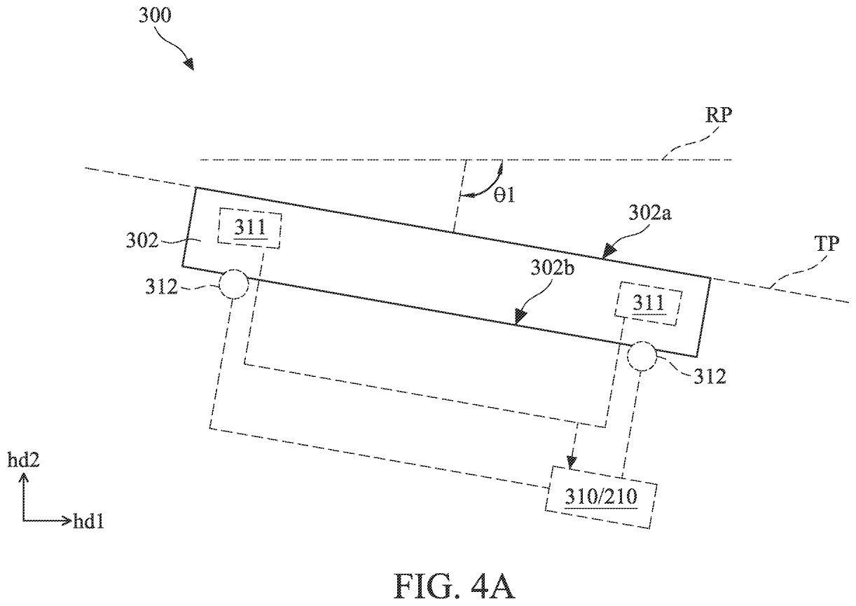

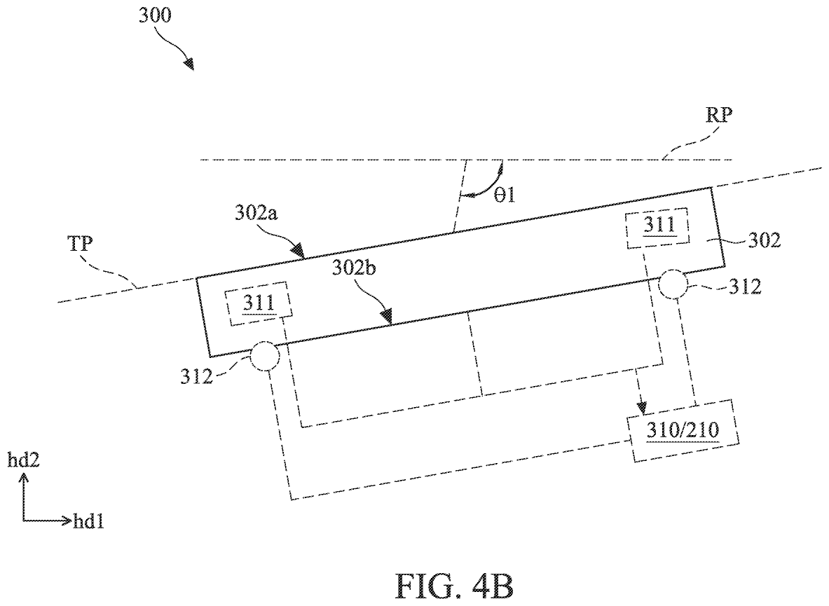

Referring to FIGS. 3A and 3B, in various embodiments the bond stage 300 may be tiltable/rotatable about two rotation axes, a1 and a2. The rotation axis a1 is perpendicular to the rotation axis a2. In the embodiment shown in FIG. 1B, the first axis a1 is parallel to the first horizontal direction hd1, and the second axis a2 is parallel to a second horizontal direction hd2 that is perpendicular to the first horizontal direction hd1. Each of the actuator 312 may also be configured to move vertically with respect to the reference plane RP. In various embodiments, the tilt motion of the bond stage 300 may change the orientation of the tool plane TP defined by the top surface 302t of the bonding platform 302 with respect to the reference plane RP. This is illustrated in FIGS. 4A and 4B, which are vertical cross-sectional views illustrating the tilt motion of the bond stage 300 with respect to the reference plane RP. In FIG. 4A, the bond stage 300 is tilted, by, for example, the actuator 312b, in a about the first rotation axis with respect to the reference plane RP. The other three actuators, such as the actuators 312a, 312c, and 312d, may remain still while the actuator 312b is tilting. In some embodiments, one or more of the other three actuators (e.g., actuators 312a, 312c, and 312d) may move vertically while the first actuator (e.g., actuator 312b) is tilting. In FIG. 4B, the bond stage 300 is tilted, by, for example, the actuator 312d, in a second rotation axis with respect to the reference plane RP. Likewise, the other three actuators, such as the actuators 312a, 312b, and 312c, may remain still while the actuator 312d is tilting. In some embodiments, one or more of the other three actuators (e.g., actuators 312a, 312b, and 312c) may move vertically while the first actuator (e.g., actuator 312d) is tilting. In both FIGS. 4A and 4B, the tool plane TP is not parallel to the reference plane RP, and the angles θ1 and 02 between line 315 and the reference plane RP are not 90°. For example, the bond stage 300 may be tilted during a first tilt motion such that the angle θ1 between line 315 and the reference plane RP is greater than 90° (e.g., FIG. 4A), and the bond stage 300 may be titled during a second tilt motion such that the angle θ2 between line 315 and the reference plane RP is less than 90° (e.g., FIG. 4B). In some embodiments, the tilt motion of the bond stage 400 may enable the peripheral edges of the bond stage 300 to be vertically displaced by at least about ±50 μm, such as about ±100 μm, including about ±150 μm, or more, as compared to the initial orientation of the bond stage 300.

The actuator 312 of the bond stage 300 may be configured to provide the tilt motion of the bonding platform 302 as shown in FIGS. 4A and 4B. In some embodiments, the actuator 312 may be a motorized system including one or more motors, linear and/or rotary actuators, sliders, cams, joints, linkages, and/or feedback sensors (e.g., encoders), etc., or a combination thereof, that may be configured to controllably tilt and/or move the top surface 302t of the bonding platform 302 of the bond stage 300 about at least a first rotation axis a1, and in some embodiments, about both the first rotation axis a1 and a second rotation axis a2 that is perpendicular to the first rotation axis a1. Although the actuator 312 in the embodiment of FIGS. 4A and 4B is shown coupled to the bottom surface 302b of the bonding platform 302, it will be understood that the actuator 312 may be located in other locations on the bond stage 300, such as the sidewall 302s of the bonding platform 302, or within the bond stage 300 such that an upper portion of the bond stage 300 including the top surface 302t may be tiltable with respect to a lower portion of the bond stage 300.

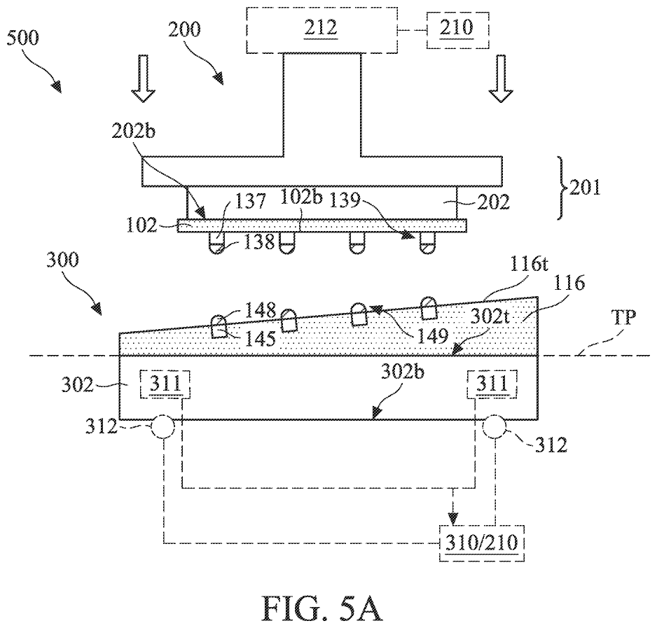

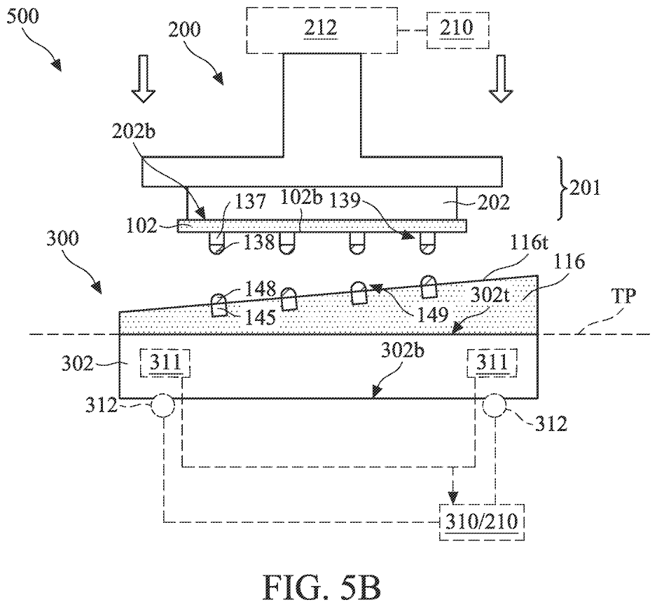

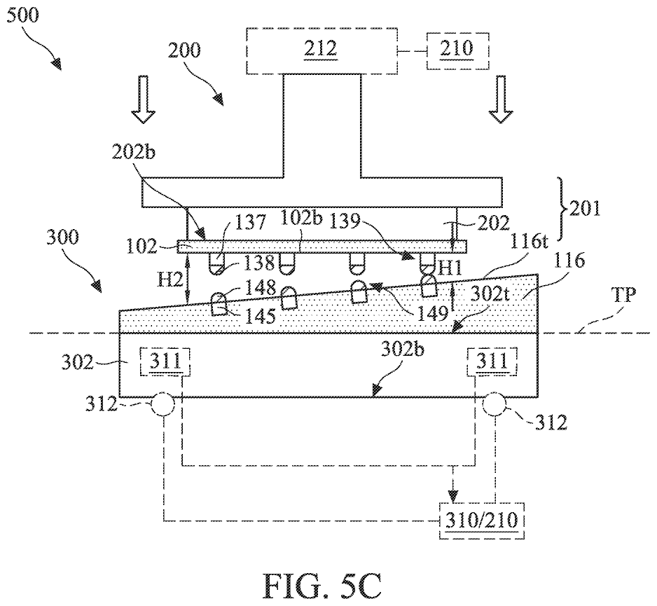

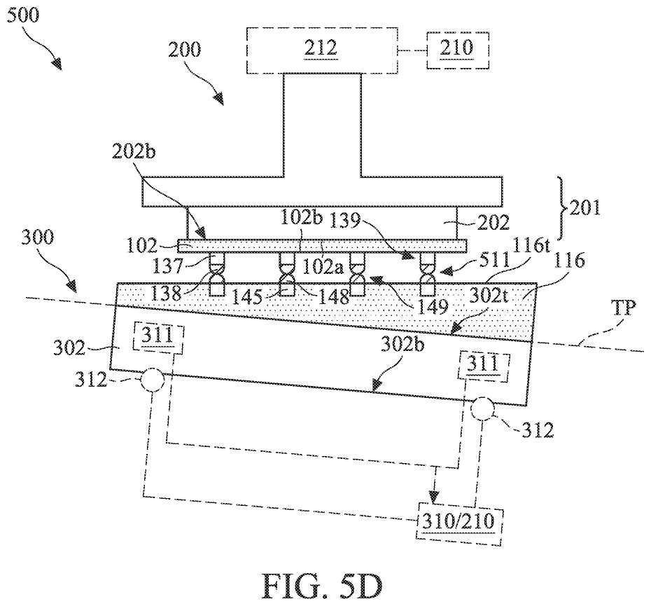

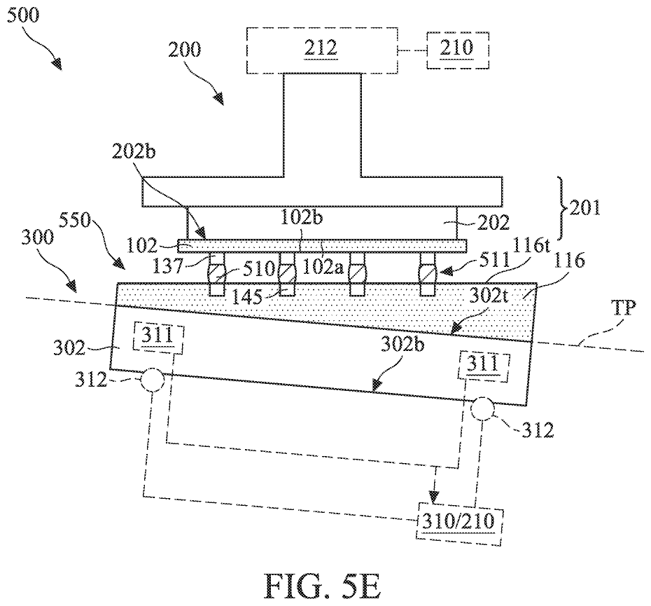

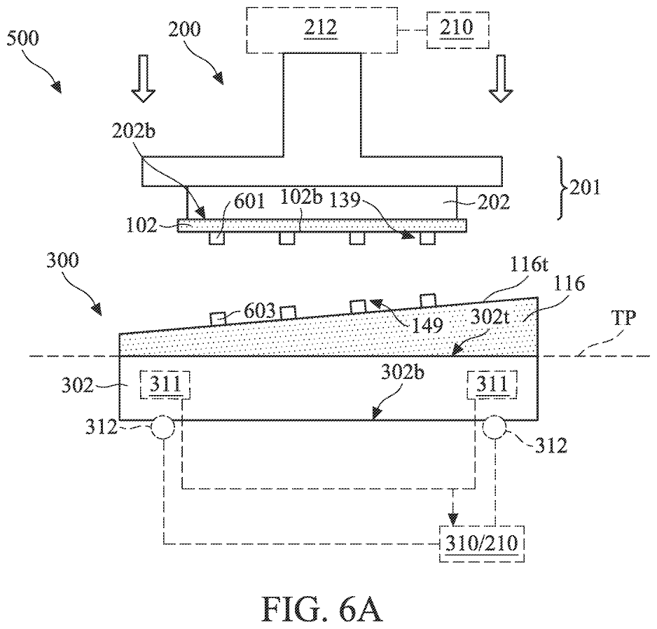

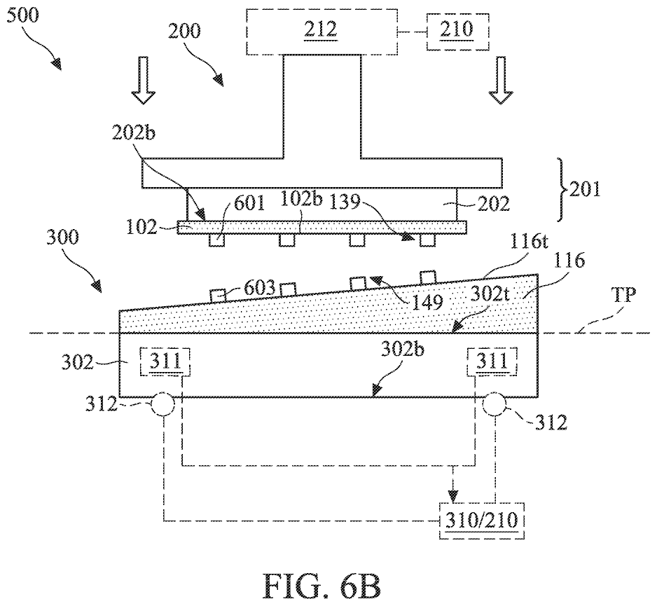

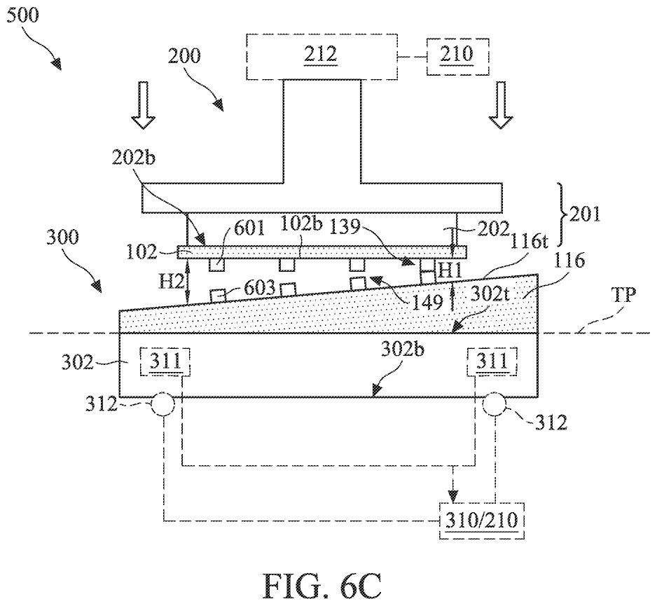

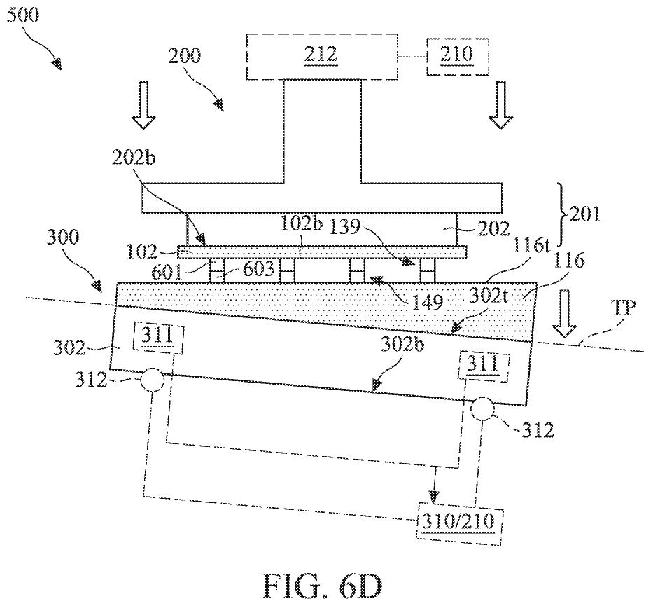

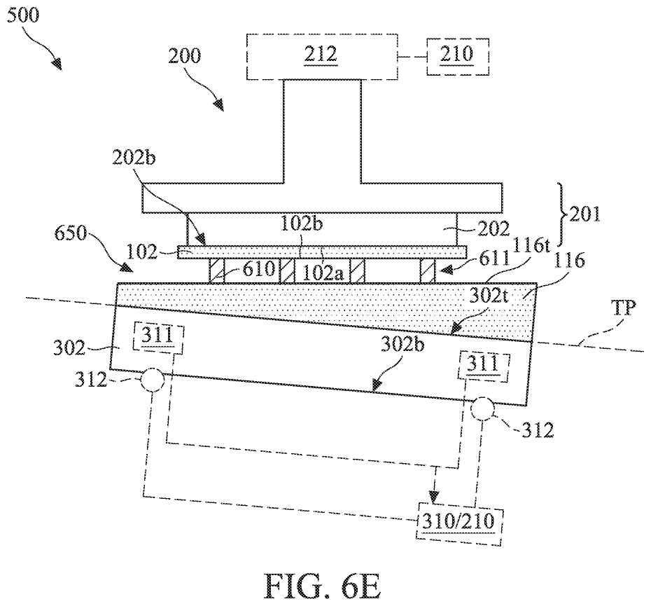

In operation, a first actuator (e.g., actuator 212) may move the bond head 201 and the semiconductor die towards a surface of a target substrate disposed on a tiltable bond stage (e.g., bond stage 300), a second actuator (e.g., actuator 312) may move and/or tilt the bond stage when an initial contact between a first region of the semiconductor die (e.g., a first semiconductor IC die) and a first region of the target substrate (e.g., a first IC die or bonding pad) is detected by at least one contact sensor (e.g., contact sensor 311) disposed at the bond stage. In response to detecting the initial contact between the semiconductor die and the first region of the target substrate, the second actuator may continue to tilt or move the bond stage (and therefore the target substrate disposed thereon) to bring a second region of the target substrate (e.g., a second IC die or bonding pad) into contact with a second region of the semiconductor die (e.g., a second semiconductor IC die), as will be discussed in more detail below with respect to FIGS. 5A-5E and 6A-6E.

FIGS. 5A-5E are sequential vertical cross-sectional views illustrating a process of bonding a semiconductor IC die 102 to a target substrate 116 using a die bonding tool 500 according to various embodiments of the present disclosure. The die bonding tool 500 generally includes the bond head assembly 200 and the bond stage 300 as discussed above. Referring to FIG. 5A, a semiconductor IC die 102 may be secured against the lower surface 202b of the nozzle plate 202 of the bond head assembly 200 via a suction force. The semiconductor IC die 102 may include a semiconductor material, such as silicon, having a number of circuit components and elements formed on and/or within the semiconductor material. Semiconductor IC dies 102 are typically fabricated by sequentially depositing insulating or dielectric layers, conductive layers, and semiconductive layers of material over a semiconductor substrate, patterning the various material layers using lithography to form integrated circuits, and separating individual dies from the wafer such as by sawing between the integrated circuits along scribe lines. In some embodiments, the semiconductor IC die 102 may be a system-on-chip (SoC) die. An SoC die may include, for example, an application processor die, a central processing unit die, and/or a graphic processing unit die. In some embodiments, the semiconductor IC die 105 may be a memory die. A memory die may include, for example, a dynamic random access memory (DRAM) die, and/or a high bandwidth memory (HBM) die. Other suitable semiconductor IC dies 102, such as an application-specific integrated circuit (ASIC) die, an analog die, a sensor die, a wireless and radio frequency die, a voltage regulator die, and the like, are within the contemplated scope of disclosure.

The semiconductor IC die 102 may have a plurality of die-side bonding structures 130 located over a lower surface 102b of the semiconductor IC die 102. In the embodiment shown in FIGS. 5A-5E, the die-side bonding structures 130 include a plurality of metal pillars 137 on the lower surface 102b of the semiconductor IC die 102 and solder material portions 138 (e.g., solder balls) on each of the metal pillars 137. The semiconductor IC die 102 in this embodiment may be bonded to the target substrate 116 using a solder-based bonding method. In some embodiments, the metal pillars 137 may include copper or a copper alloy. Other suitable conductive materials for the metal pillars 137, including nickel, platinum, palladium, gold, aluminum, etc., including combinations and alloys thereof, may be utilized. The metal pillars 137 may be formed using any number of suitable techniques, including physical vapor deposition (PVD), chemical vapor deposition (CVD), electrochemical deposition (ECD), molecular beam epitaxy (MBE), atomic layer deposition (ALD), electroplating, etc. Each of the metal pillars 137 may contact a conductive bonding pad and/or an under bump metallization (UBM) (not shown) on the lower surface 102b of the semiconductor IC die 102. In some embodiments, an optional conductive cap layer (not shown) may be formed between the metal pillar 137 and the solder material portion 138. For example, in an embodiment in which the metal pillar 137 may be formed of copper, a conductive cap layer formed of nickel may be used. Other materials, such as platinum, gold, silver, combinations thereof, etc., may also be used. The solder material portions 138 may be formed over the ends of the respective metal pillars 137 and/or on the optional conductive cap layers. In some embodiments, the solder material portion 138 may directly formed on the bonding pads/UBM on the lower surface 102b of the semiconductor IC die 102, for example, in embodiments where metal pillars 137 and the optional conductive cap layers are omitted. The solder material portions 138 may include SnPb, a high-Pb material, a Sn-based solder, a lead-free solder, or other suitable conductive materials, as examples. In some embodiments, a center-to-center spacing (i.e., pitch) between the die-side bonding structures 139 on the lower surface 114 of the semiconductor IC die 105 utilizing a solder-based bonding method may about 150 μm or less.

Referring again to FIG. 5A, the actuator 212 may move the bond head 201 along one or more horizontal directions to align the semiconductor IC die 102 over a portion of a target substrate 116 to which the semiconductor IC die 102 is to be bonded. The target substrate 116 is disposed on the bond stage 300. In some embodiments, the target substrate 116 may be a semiconductor material substrate (i.e., a semiconductor wafer). The semiconductor material substrate may have one or more integrated circuits formed on or in the substrate 116. Other suitable target substrates, such as glass, ceramic and/or organic material substrates, are within the contemplated scope of disclosure.

The target substrate 116 may have a plurality of substrate-side bonding structures 149 located over a top surface 116t of the target substrate 116. Each substrate-side bonding structure 149 may be disposed over and in electrical communication with a corresponding integrated circuit die (e.g., die 126 in FIG. 1). The substrate-side bonding structures 149 may include bonding pads 145 and solder material portions 148 (e.g., solder balls) on each of the bonding pads 145. The arrangement and spacing (i.e., pitch) of the substrate-side bonding structures 149 may be the same as the arrangement and spacing of the die-side bonding structures 139 located on the lower surface of the semiconductor IC die 102. In some embodiments, either the solder material portions 148 of the substrate-side bonding structures 149 or the solder material portions 138 of the die-side bonding structures 139 may be omitted such that a solder-based bonding of the semiconductor IC die 102 to the target substrate 116 may be accomplished using a single set of solder material portions (e.g., solder balls.

In some embodiments, the top surface 116t of the target substrate 116 and/or the lower surface 102b of the semiconductor IC die 102 may not be parallel to the tool plane TP defined by the top surface 302t of the bonding platform 302 of the bond stage 300. This may be due to variations in the thickness and/or the surface planarity of either the target substrate 116, the semiconductor IC die 102, or both. As shown in FIG. 5A, for example, the top surface 116t of the target substrate 116 slopes upward from left to right and is not parallel to the tool plane TP which extends horizontally. In some cases, the variation in vertical elevation of the top surface 302t of the target substrate 116 over the region in which the semiconductor IC die 102 is to be bonded may be greater than 18 μm. As noted above, such non-uniformities in the interfacing surfaces 116t and 102b of the target substrate 116 and the semiconductor IC die 102 may inhibit effective contact between the respective bonding structures 139 and 149, resulting in poor bonding between the semiconductor IC die 102 and the target substrate 116. Various embodiments may compensate for such surface non-uniformities by utilizing a bond stage 300 having a self-tilt capability, as described in further detail below.

FIG. 5B is a vertical cross-sectional view of the die bonding tool 500 illustrating the bond head 201 and the semiconductor IC die 102 attached thereto moved vertically downward towards the top surface 116t of the target substrate 116 according to an embodiment of the present disclosure. In various embodiments, the die bonding tool 500 may perform a “soft contact” process to bring the die-side bonding structures 139 on the lower surface 102b of the semiconductor IC die 102 into contact with the corresponding substrate-side bonding structures 149 on the top surface 116t of the target substrate 116. The soft contact process may include a step of moving the bond head 201 and the semiconductor IC die 102 vertically downward (as indicated by the arrows in FIG. 5B) until an initial contact is made between one or more die-side bonding structures 139 on the semiconductor IC die 102 and the corresponding substrate-side bonding structures 149 on the target substrate 116.

FIG. 5C is a vertical cross-sectional view of the die bonding tool 500 illustrating an initial contact between a die-side bonding structure 139 on the semiconductor IC die 102 and the corresponding substrate-side bonding structure 149 on the target substrate 116 according to an embodiment of the present disclosure. The bond head 201 and the semiconductor IC die 102 attached thereto may continue to move vertically downward towards the top surface 116t of the target substrate 116 until the system controller 210 determines that an initial contact has been made between one or more die-side bonding structures 139 on the semiconductor IC die 102 and the corresponding substrate-side bonding structure(s) 149 on the target substrate 116. The system controller 210 may determine that an initial contact has been made based on feedback signals received from the at least one contact sensor 311 of the bond stage 300.

The system controller 310/210 may also determine the region of the semiconductor IC die 102 that made the initial contact with the target substrate 116 based on the signal feedback from the at least one contact sensor 311 on the bond stage 300. In one non-limiting embodiment, the at least one contact sensor 311 may include a plurality of force sensors located in different regions of the bond stage 300. As the initial contact is made between one or more die-side bonding structures 139 on the semiconductor IC die 102 and the corresponding substrate-side bonding structure(s) 149 on the target substrate 116, the resulting force of the contact may be transmitted from the substrate-side bonding structure(s) 149 through the target substrate 116 to the bond stage 300, where the force may be detected by a force sensor located within the bond stage 300 that overlies or is in nearest proximity to the location of the initial contact between the semiconductor IC die 102 and the target substrate 116. In the exemplary embodiment shown in FIG. 5C, for example, the initial contact between a die-side bonding structure 139 and the corresponding substrate-side bonding structure 149 occurs on the right-hand side of the semiconductor IC die 102. Thus, the force resulting from this initial contact may be detected by the contact sensor 311 located on the right hand side of bond stage 300, which may transmit force feedback signals to the system controller 310/210. Based on the force feedback signals, the system controller 310 may determine that at least one substrate-side bonding structure 149 on the right-hand side of the bond stage 300 is in contact with the corresponding die-side bonding structures 139. Other substrate-side bonding structures 149 on the target substrate 116 may not be in contact with the corresponding die-side bonding structures 139 of the semiconductor IC die 102.

In embodiments in which the at least one contact sensor 311 includes one or more encoders, the system controller 310/210 may determine that an initial contact has been made based on a change in encoder feedback signals. The change in encoder feedback signals may be due to an increase in resistance to further downward movement by the bond head 201 resulting from the initial contact between at least one die-side bonding structure 139 and substrate-side bonding structure 149 pair. The system controller 310/210 may determine the location of the initial contact based on differences in encoder feedback signals measuring the position and/or motion of different regions of the bond stage 300.

Referring again to FIG. 5C, because the top surface 116t of the target substrate 116 is not parallel to the tool plane TP, there is a variation in the gap height, H, between the lower surface 102b of the semiconductor IC die 102 and the top surface 116t of the target substrate 116. In this example, the maximum height gap, H2, is located proximate to the left-hand side of the semiconductor IC die 102 while the minimum height gap, H1, is located proximate to the right-hand side of the semiconductor IC die 102. In some embodiments, a difference between the maximum height gap (e.g., H2) and the minimum height gap (e.g., H1) upon the initial contact with the target substrate 116 may be greater than 15 μm, such as greater than 20 μm (e.g., ≥30 μm), including greater than 50 μm. Such variations in gap height may result in joint height differences in different regions of the semiconductor IC die 102 following the bonding of the semiconductor IC die 102 to the target substrate 116. Large variations in joint heights may result in poor or defective connections between semiconductor IC die 102 and the target substrate 116. Thus, it is generally desirable to minimize the total joint height difference (i.e., the difference between the maximum joint height and the minimum joint height of all of the bonds formed between the semiconductor IC die 102 and the target substrate 116) in the bonded device structure.

FIG. 5D is a vertical cross-sectional view of the die bonding tool 500 illustrating the bond stage 300 and the target substrate 116 disposed thereon tilted to bring additional substrate-side bonding structures 149 into contact with the corresponding die-side bonding structure 139 on the semiconductor IC die 102, in accordance with an embodiment of the present disclosure. While the bond stage 300 is tilted, the bond head 201 and the semiconductor IC die 102 attached thereto may continue to move vertically downward towards the top surface 116t of the target substrate 116. Following the initial contact between the semiconductor IC die 102 and the target substrate 116, the soft contact process may include a step of tilting the bond stage 300 (and therefore the target substrate 116 disposed thereon) with respect to the semiconductor IC die 102 to bring additional substrate-side bonding structures 149 into contact with the corresponding die-side bonding structures 139. In some embodiments, the tilt motion of the bond stage 300 may bring all of the die-side bonding structures 139 of the semiconductor IC die 102 into contact with the corresponding substrate-side bonding structures 149 of the target substrate 116. This may provide improved contact between the semiconductor IC die 102 and the target substrate 116 and result in more effective bonding between these components.

Referring again to FIG. 5D, the system controller 310/210 may control the actuator 312 to cause the bond stage 300 to tilt about at least one tilt axis (e.g., axis a1 and/or axis a2 in FIG. 3B) to bring additional die-side bonding structures 139 into contact with the corresponding substrate-side bonding structures 149. In this regard, the system controller 110 may control the actuator 312 to cause the TP of the bond stage 300 to match the angle of the lower surface 102b of the semiconductor IC die 102. In an embodiment bond stage 300 having contact sensors 311 configured to detect contact in four angular regions of the bond stage 300 such as shown in FIG. 3B, when the initial contact with the target substrate 116 is detected by the contact sensor 311 (e.g., contact sensor 311b) in a particular angular region of the bond stage 300, the system controller 310/210 may be operated to cause the actuator 312 (e.g., actuator 312b) associated with the contact sensor 311 (e.g., contact sensor 311b) to move the bond stage 300 downwards or tilt/rotate the bond stage 300 about the tilt axis (e.g., axis a2) while the actuators 312 (e.g., actuators 312a, 312c, 312d) at the other three angular regions of the bond stage 300 remain still. In embodiments in which the initial contact with the target substrate 116 is detected in two angular regions of the bond stage 300, the system controller 310/210 may control the actuator 312 (e.g., actuators 312b, 312c) to move the bond stage 300 downwards or tilt about the tilt axis (e.g., axis a2) while the actuators 312 (e.g., actuators 312a and 312d) at the other two angular regions of the bond stage 300 remain still. As discussed above, in some embodiments, the tilt motion of the bond stage 300 may be accompanied by a small vertical downward movement of the bond head 201 to maintain adequate contact between the die-side bonding structure 139 and the substrate-side bonding structures 149 in regions of the semiconductor IC die 102 that are already in contact with the target substrate 116.

In some embodiments, the tilt motion of the bond stage 300 may continue until a contact criterion is met. The contact criterion may include, for example, a number of contact sensors 311 in different regions of the bond stage 300 that detect contact between the die-side bonding structures 139 and the corresponding substrate-side bonding structures 149 (e.g., a percentage of contact sensors 311 that detect contact, such as all contact sensors 311 of the bond stage 300), and/or an amount of contact detected between the die-side bonding structures 139 and the corresponding substrate-side bonding structures 149 (e.g., the magnitude of contact force detected by all or a portion of the contact sensors 311 on the bond stage 300 exceeds a threshold value). The system controller 310/210 may control the actuator 312 to stop the tilt motion of the bond stage 300 based on a determination that the contact criterion is met.

FIG. 5E is a vertical cross-sectional view of the die bonding tool 500 following a bonding process that bonds the semiconductor IC die 102 to the target substrate 116 to form a bonded device structure 550 according to an embodiment of the present disclosure. Referring to FIG. 5E, when the die-side bonding structures 139 on the semiconductor IC die 102 are brought into contact with the substrate-side bonding structures 149 on the target substrate 116, a bonding process may be performed to bond the semiconductor IC die 102 to the target substrate 116.

FIGS. 5A-5E illustrate a solder-based bonding method that includes the formation of solder bonds 511 between the lower surface 102b of the semiconductor IC die 102 and the top surface 116t of the target substrate 116. Each of the solder bonds 511 may include a solder connection 510 located between a metal pillar 137 on the semiconductor IC die 102 and a bonding pad 145 on the target substrate 116. The solder bonds 511 may be formed via a reflow process that includes the application of heat and/or pressure to cause the solder material portions 138 and 148 to reflow and solidify to form the solder bonds 511 which provide a mechanical and electrical connection between respective metal pillar 137 and bonding pad 145 pairs. In some embodiments, the bond stage 300 may apply a compressive force to the target substrate 116 during the bonding process. Additionally or alternatively, the bond head 201 may apply a compressive force to the top surface 102a of the semiconductor IC die 102. In either case, the compression force may be in a direction that is normal to the top surface 302t of the bonding platform 302 (i.e., perpendicular to the tool plane TP). The tool plane TP may be tilted with respect to its initial orientation (e.g., a horizontal orientation as shown in FIG. 4A). In some embodiments, the semiconductor IC die 102 and the target substrate 116 may be subjected to an elevated temperature, such as a temperature between about 150° C. and about 350° C., during the bonding process. In some embodiments, the elevated temperature may be provided by a heating mechanism (not shown) located on the die bonding tool 500, such as on or within the bond stage 300 and/or the bond head 201.

In various embodiments, the die bonding tool 500 may release the semiconductor IC die 102 from the lower surface 102b of the nozzle plate 202 either prior to, during, or following the bonding process. The die bonding tool 500 may release the semiconductor die 102 from the lower surface 102b of the nozzle plate 202 by turning off/disconnecting the vacuum source and/or by providing an ambient or positive pressure within the fluid conduit 219, the plenum 217 and the fluid conduits 216 (FIG. 2), thereby releasing the suction force at the openings 218 in the nozzle plate 202. Following the release of the semiconductor IC die 102 from the lower surface 102b of the nozzle plate 202, the system controller 210 may cause the actuator 212 to move the bond head 201 vertically upwards and away from the semiconductor IC die 102.

Referring again to FIG. 5E, the bonded device structure 550 includes a plurality of solder bonds 511 that mechanically and electrically couple the semiconductor IC die 102 to the bonding pads 145 disposed in the target substrate 116. In some embodiments, the center-to-center spacing (i.e., pitch) between each of the solder bonds 511 may be about 150 μm or less. Each of the solder bonds 511 may have a joint height (JH) between the upper surface 116t of the target substrate 116 and the lower surface 102b of the semiconductor IC die 102. In various embodiments, a difference between a maximum joint height JH and a minimum joint height JH across all of the solder bonds 511 of the bonded device structure 550 may be 15 μm or less. Accordingly, the joint heights JH of the solder bonds 511 may be relatively uniform which may provide for a more effective bonding between the semiconductor IC die 102 and the target substrate 116.

FIGS. 6A-6E are sequential vertical cross-section views illustrating an alternative process of bonding a semiconductor IC die 102 to a target substrate 116 using the die bonding tool 500 according to various embodiments of the present disclosure. The bonding process shown in FIGS. 6A-6E may be similar to the bonding process described above with reference to FIGS. 5A-5E. Thus, repeated discussion of common structures and operations of the die bonding tool 500, the semiconductor IC die 102 and the target substrate 116 are omitted for brevity. The bonding process of FIGS. 6A-6E differs from the bonding process of FIGS. 5A-5E in that a different bonding mechanism is utilized to bond the semiconductor IC die 102 to the target substrate 116. In the embodiment of FIGS. 6A-6E, the die-side bonding structures 139 located over the lower surface 102b of the semiconductor IC die 102 and the substrate-side bonding structures 149 located over the upper surface 116t of the target substrate 116 may each include metal connectors 601, 603 (e.g., metal bonding pads, bumps, pillars, studs, etc.) that may be bonded together using a direct bonding process that does not require the use of solder material portions 138, 148 (e.g., solder balls) located between the respective metal connectors 601 and 603.

Referring to FIG. 6A, a semiconductor IC die 102 is shown secured against the lower surface 202b of the nozzle plate 202 of the bond head 201 via a vacuum or suction force. The semiconductor IC die 102 includes a plurality of die-side bonding structures 139 located over the lower surface 102b of the semiconductor IC die 102 opposite to the bond head 201. In the embodiment shown in FIGS. 6A-6E, the die-side bonding structures 1e9 include a plurality of first metal connectors 601 (e.g., bonding pads, pillars, studs, bumps, etc.) on the lower surface 102b of the semiconductor IC die 102. In some embodiments, the first metal connectors 601 may include copper or a copper alloy. Other suitable conductive materials for the first metal connectors 601, including nickel, platinum, palladium, gold, aluminum, etc., including combinations and alloys thereof, may be utilized. The first metal connectors 601 may be formed using a suitable technique as described above. In some embodiments, a center-to-center spacing (i.e., pitch) between the die-side bonding structures 139 on the lower surface 102b of the semiconductor IC die 102 utilizing a direct bonding method may about 25 μm or less.

The target substrate 116 may have a plurality of substrate-side bonding structures 149 located over the upper surface 116t of the target substrate 116. In the embodiment shown in FIGS. 6A-6E, the substrate-side bonding structures 149 include a plurality of second metal connectors 603 (e.g., bonding pads, pillars, studs, bumps, etc.) on the top surface 116 of the target substrate 116. In some embodiments, the second metal connectors 603 may include copper or a copper alloy. Other suitable conductive materials for the second metal connectors 603, including nickel, platinum, palladium, gold, aluminum, etc., including combinations and alloys thereof, may be utilized. The second metal connectors 603 may be formed using a suitable technique as described above. In some embodiments, the second metal connectors 603 on the target substrate 116 may have the same size and shape and may be composed of the same material(s) as the first metal connectors 601 on the semiconductor IC die 102. Alternatively, the second metal connectors 603 may have a different size and shape and/or may be composed of different material(s) as the first metal connectors 601 on the semiconductor IC die 102. The arrangement and spacing (i.e., pitch) of the second metal connectors 603 on the target substrate 116 may be the same as the arrangement and spacing of the first metal connectors on the semiconductor IC die 102.

In various embodiments, the die-side bonding structures 139 and the substrate-side bonding structures 149 may be free of solder material. Alternatively, one or both of the die-side bonding structures 139 and the substrate-side bonding structures 149 may include a thin (e.g., ≤3 μm thick) surface layer of solder material over the metal connectors 601, 603. In various embodiments, bonding of the die-side bonding structures 139 and the substrate-side bonding structures 149 may be accomplished using a direct bonding process. In a direct bonding process, pairs of first and second metal connectors 601 and 603 may be bonded together without solder disposed between the two metal connectors 601 and 603. For example, the direct bonding may be a copper-to-copper bonding or a gold-to-gold bonding. The methods for performing direct bonding may include thermo-compression bonding (TCB). In a direct bonding process, the first metal connectors 601 of the semiconductor IC die 102 may be aligned with, and placed against, the second metal connectors 603 of the target substrate 116. A compressive force may then be applied to press the semiconductor IC die 102 and the target substrate 116 against one another. During the bonding process, the semiconductor IC die 102 and the target substrate 116 may also be heated. With the applied pressure and optionally the elevated temperature, surface portions of the first metal connectors 601 of the semiconductor IC die 102 and the second metal connectors 603 of the target substrate 116 may inter-diffuse, so that bonds may be formed. In some embodiments, a solder layer with thickness less than 3 μm may be added to each side of the metal connectors 601 and 603 of the semiconductor IC die 102 and the target substrate 116. In the direct bonding, the solder layers may be in contact with one another, and may be bonded with underlying non-flowable portions of the first metal connectors 601 and the second metal connectors 603.

FIG. 6B is a vertical cross-sectional view of the die bonding tool 500 illustrating the bond head 201 and the semiconductor IC die 102 attached thereto moved vertically downward towards the top surface 116t of the target substrate 116 according to an embodiment of the present disclosure. As in the embodiment of FIGS. 5A-5E, the die bonding tool 100 may perform a “soft contact” process to bring the die-side bonding structures 139 on the lower surface 102b of the semiconductor IC die 102 into contact with the corresponding substrate-side bonding structures 149 on the upper surface 116t of the target substrate 116. The soft contact process may include a step of moving the bond head 201 and the semiconductor IC die 102 vertically downward (as indicated by the arrows in FIG. 6B) until an initial contact is made between one or more die-side bonding structures 139 on the semiconductor IC die 125 and the corresponding substrate-side bonding structures 149 on the target substrate 116.

FIG. 6C is a vertical cross-sectional view of the die bonding tool 500 illustrating an initial contact between a die-side bonding structure 139 on the semiconductor IC die 102 and the corresponding substrate-side bonding structure 149 on the target substrate 116 according to an embodiment of the present disclosure. As in the embodiment of FIGS. 5A-5E, the top surface 116t of the target substrate 116 in the embodiment of FIGS. 6A-6E is not parallel to the tool plane TP defined by the top surface 302t of the bonding platform 302 of the bond stage 300. In some embodiments, the variation in vertical elevation of the top surface 116t of the target substrate 116 over the region of the target substrate 116 to which the semiconductor IC die is to be bonded may be greater than 18 μm. Accordingly, an initial contact between one or more die-side bonding structures 139 of the semiconductor IC die 102 and the corresponding substrate-side bonding structures 149 of the target substrate 116 may occur in a particular region of the semiconductor IC die 102 (e.g., the right-hand side of the semiconductor IC die 102 as shown in FIG. 6C), while die-side bonding structures 139 in other regions of the semiconductor IC die 102 may not contact the corresponding substrate-side bonding structures 149 on the target substrate 116. As in the embodiment described above with reference to FIGS. 5A-5E, the system controller 310/210 of the die bonding tool 500 may determine that an initial contact has been made between the semiconductor IC die 102 and the target substrate 116 and the region of the semiconductor IC die 102 that made the initial contact based on feedback signals received from the at least one contact sensor 311 of the die bonding tool 500.

Referring again to FIG. 6C, when the lower surface 102b of the semiconductor IC die 102 is not parallel to the tool plane TP, there may be a variation in the gap height, H, between the lower surface 102b of the semiconductor IC die 102 and the top surface 116t of the target substrate 116. In this example, the maximum height gap, H2, is located proximate to the left-hand side of the semiconductor IC die 102 while the minimum height gap, H1, is located proximate to the right-hand side of the semiconductor IC die 102. In some embodiments, a difference between the maximum height gap (e.g., H2) and the minimum height gap (e.g., H1) over the semiconductor IC die 102 upon the initial contact with the target substrate 116 may be greater than 15 μm, such as greater than 20 μm (e.g., ≥30 μm), including greater than 50 μm. Such variations in gap height may result in joint height differences in different regions of the semiconductor IC die 102 following the bonding of the semiconductor IC die 102 to the target substrate 116. Large variations in joint heights may result in poor or defective connections between semiconductor IC die 102 and the target substrate 116.

FIG. 6D is a vertical cross-sectional view of the die bonding tool 500 illustrating the bond stage 300 and the target substrate 116 disposed thereon tilted to bring additional substrate-side bonding structures 149 into contact with the corresponding die-side bonding structure 139 on the semiconductor IC die 102, in accordance with an embodiment of the present disclosure. While the bond stage 300 is tilted, the bond head 201 and the semiconductor IC die 102 attached thereto may continue to move vertically downward towards the top surface 116t of the target substrate 116. Following the initial contact between the semiconductor IC die 102 and the target substrate 116, the soft contact process may include a step of tilting the bond stage 300 (and therefore the target substrate 116 disposed thereon) with respect to the semiconductor IC die 102 to bring additional substrate-side bonding structures 149 into contact with the corresponding die-side bonding structures 139. In some embodiments, the tilt motion of the bond stage 300 may bring all of the die-side bonding structures 139 of the semiconductor IC die 102 into contact with the corresponding substrate-side bonding structures 149 of the target substrate 116. This may provide improved contact between the semiconductor IC die 102 and the target substrate 116 and result in more effective bonding between these components.

Referring again to FIG. 6D, the system controller 310/210 may control the actuator 312 to cause the bond stage 300 to tilt about at least one tilt axis (e.g., axis a1 and/or axis a2 in FIG. 3B) to bring additional die-side bonding structures 139 into contact with the corresponding substrate-side bonding structures 149. In this regard, the system controller 110 may control the actuator 312 to cause the TP of the bond stage 300 to match the angle of the lower surface 102b of the semiconductor IC die 102. In an embodiment bond stage 300 having contact sensors 311 configured to detect contact in four angular regions of the bond stage 300 such as shown in FIG. 3B, when the initial contact with the target substrate 116 is detected by the contact sensor 311 (e.g., contact sensor 311b) in a particular angular region of the bond stage 300, the system controller 310/210 may be operated to cause the actuator 312 (e.g., actuator 312b) associated with the contact sensor 311 (e.g., contact sensor 311b) to move the bond stage 300 downwards or tilt/rotate the bond stage 300 about the tilt axis (e.g., axis a2) while the actuators 312 (e.g., actuators 312a, 312c, 312d) at the other three angular regions of the bond stage 300 remain still. In embodiments in which the initial contact with the target substrate 116 is detected in two angular regions of the bond stage 300, the system controller 310/210 may control the actuator 312 (e.g., actuators 312b, 312c) to move the bond stage 300 downwards or tilt about the tilt axis (e.g., axis a2) while the actuators 312 (e.g., actuators 312a and 312d) at the other two angular regions of the bond stage 300 remain still. As discussed above, in some embodiments, the tilt motion of the bond stage 300 may be accompanied by a small vertical downward movement of the bond head 201 to maintain adequate contact between the die-side bonding structure 139 and the substrate-side bonding structures 149 in regions of the semiconductor IC die 102 that are already in contact with the target substrate 116.

In some embodiments, the tilt motion of the bond stage 300 may continue until a contact criterion is met. The contact criterion may include, for example, a number of contact sensors 311 in different regions of the bond stage 300 that detect contact between the die-side bonding structures 139 and the corresponding substrate-side bonding structures 149 (e.g., a percentage of contact sensors 311 that detect contact, such as all contact sensors 311 of the bond stage 300), and/or an amount of contact detected between the die-side bonding structures 139 and the corresponding substrate-side bonding structures 149 (e.g., the magnitude of contact force detected by all or a portion of the contact sensors 311 on the bond stage 300 exceeds a threshold value). The system controller 310/210 may control the actuator 312 to stop the tilt motion of the bond stage 300 based on a determination that the contact criterion is met.

FIG. 6E is a vertical cross-sectional view of the die bonding tool 500 following a bonding process that bonds the semiconductor IC die 102 to the target substrate 116 to form a bonded device structure 650 according to an embodiment of the present disclosure. Referring to FIG. 6E, when the die-side bonding structures 139 on the semiconductor IC die 102 are brought into contact with the substrate-side bonding structures 149 on the target substrate 116, a bonding process may be performed to bond the semiconductor IC die 102 to the target substrate 116.

FIGS. 6A-6E illustrate a direct bonding method that includes the formation of direct bonds 611 between the first metal connections 601 on the semiconductor IC die 102 and the second metal connections 601 on the target substrate 116. In some embodiments, the bond stage 300 may apply a compressive force to the target substrate 116 during the bonding process, as indicated by the arrows in FIG. 6E. Additionally or alternatively, the bond head 201 may apply a compressive force to the top surface 102a of the semiconductor IC die 102. In either case, the compression force may be in a direction that is normal to the top surface 302t of the bonding platform 302 (i.e., perpendicular to the tool plane TP). The tool plane TP may be tilted with respect to its initial orientation (e.g., a horizontal orientation as shown in FIG. 4A). In some embodiments, the semiconductor IC die 102 and the target substrate 116 may be subjected to an elevated temperature, such as a temperature between about 150° C. and about 350° C., during the bonding process. In some embodiments, the elevated temperature may be provided by a heating mechanism (not shown) located on the die bonding tool 500, such as on or within the bond stage 300 and/or the bond head 201.

Referring again to FIG. 6E, the bonded device structure 650 includes a plurality of direct bonds 611 that mechanically and electrically couple the semiconductor IC die 102 to a target substrate 116. In some embodiments, the center-to-center spacing (i.e., pitch) between each of the direct bonds 611 may be about 25 μm or less. Each of the direct bonds 611 may have a joint height (JH) between the top surface 116t of the target substrate 116 and the lower surface 102b of the semiconductor IC die 102. In various embodiments, a difference between a maximum joint height JH and a minimum joint height JH across all of the direct bonds 611 of the bonded device structure 650 may be 15 μm or less. Accordingly, the joint heights JH of the direct bonds 611 may be relatively uniform which may provide for a more effective bonding between the semiconductor IC die 102 and the target substrate 116.

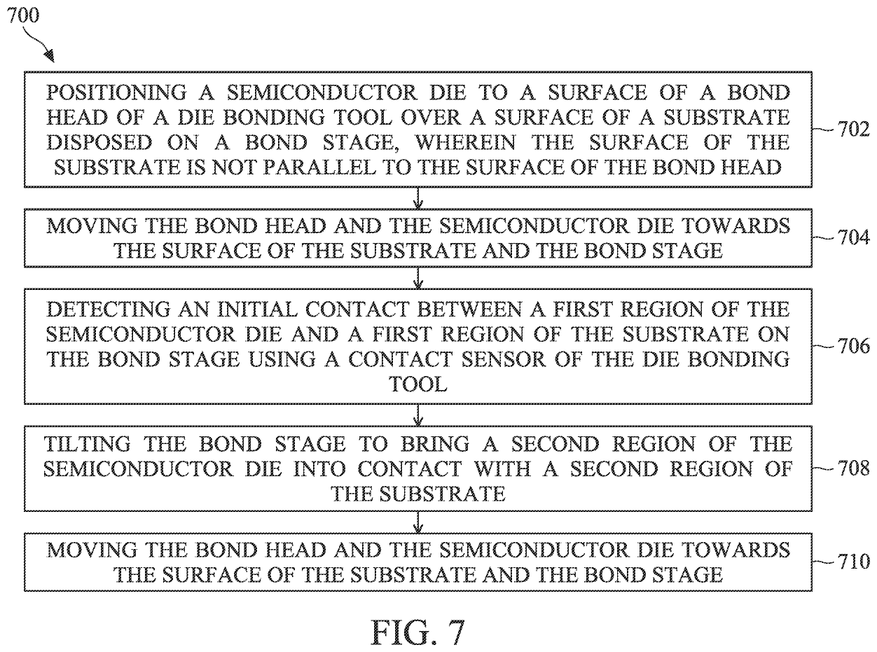

FIG. 7 is a flowchart illustrating a method 700 of bonding a semiconductor IC die 102 to a target substrate 116 using a die bonding tool 500, in accordance with some embodiments of the present disclosure. Referring to FIGS. 5A, 6A and 7, in step 702 of method 700, a semiconductor die 102 secured to a lower surface 202b of the nozzle plate 202 of the bond head 201 of the die bonding tool 500 may be positioned over a top surface 116t of a target substrate 116, where the top surface 116t of the target substrate 116 is not parallel to the planar lower surface 202b of the bond head 201. Referring to FIGS. 5B, 6B, and 7, in step 704 of method 700, the bond head 201 and the semiconductor IC die 102 may be moved toward the top surface 116t of the target substrate 116. Referring to FIGS. 5C, 6C, and 7, in step 706 of method 700, an initial contact between the semiconductor IC die 102 and the top surface 116t of the target substrate 116 may be detected in a first region of the target substrate 116 using a contact sensor 311 on the bond stage 300. Referring to FIGS. 5D, 6D, and 7, in step 708 of method 700, while the bond head 201 is moving downward, the bond stage 300 (and therefore the target substrate 116) may be tilted to bring a second region of the target substrate 116 into contact with the semiconductor IC die 102. Referring to FIGS. 5E, 6E, and 7, in step 710 of method 700, a bonding process may be performed to bond the semiconductor IC die 102 to the top surface 116t of the target substrate 116.

An embodiment is a bond stage for bonding a semiconductor integrated circuit (IC) die. The bond stage includes a bonding platform having a top surface and a bottom surface opposing the top surface, a first actuator operable to tilt the bonding platform about a first rotation axis, and a plurality of contact sensors disposed at the bonding platform.

Another embodiment is a die bonding tool. The die bonding tool includes a bond head operable to temporarily secure a first movable object, a first actuator operable to move the bond head, a bond stage having a support surface. The bond stage includes a second actuator operable to tilt the bond stage with respect to the bond head, and a contact sensor operable to detect contact forces on different regions of the bond stage. The bond stage also includes a system controller coupled to the bond head, the first actuator, the second actuator, and the contact sensor, wherein the system controller is operable to direct the first actuator to move the bond head towards a second movable object disposed on the support surface of the bond stage, direct the second actuator to tilt the bond stage about at least one tilt axis in response to the contact sensor detecting an initial contact between the first object and the second object.

A further embodiment is a method for bonding a semiconductor die to a target substrate using a die bonding tool. The method includes positioning a semiconductor die secured to a lower surface of a bond head of the die bonding tool over a top surface of the target substrate, wherein the top surface of the target substrate is not parallel to the lower surface of the bond head. The method also includes moving the bond head towards the top surface of the target substrate, detecting an initial contact between a first region of the semiconductor die and a first region of the target substrate using at least one contact sensor of the die bonding tool. The method further includes tilting the bond stage and the target substrate to bring a second region of the semiconductor die into contact with a second region of the target substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A bond stage for bonding a semiconductor integrated circuit (IC) die, comprising:
a bonding platform having a top surface and a bottom surface opposing the top surface;
a first actuator operable to tilt the bonding platform about a first axis; and
a plurality of contact sensors disposed at the bonding platform.

2. The bond stage of claim 1, further comprising:
a second actuator operable to tilt the bonding platform about a second axis that is perpendicular to the first axis.

3. The bond stage of claim 2, wherein the first and second actuators are disposed at the bottom surface of the bonding platform.

4. The bond stage of claim 3, wherein the first and second actuators are symmetrically arranged with respect to a vertical line extending through a center point of the bonding platform.

5. The bond stage of claim 1, wherein the first and second actuators are operable to move vertically.

6. The bond stage of claim 1, wherein the plurality of contact sensors comprises at least one force sensor.

7. The bond stage of claim 1, further comprising:
one or more holes extending through a body of the bonding platform.

8. The bond stage of claim 7, wherein the one or more holes are in fluidly communication with a vacuum source.

9. A die bonding tool, comprising:
a bond head operable to temporarily secure a first movable object;
a first actuator operable to move the bond head;
a bond stage having a support surface, the bond stage comprising:
a second actuator operable to tilt the bond stage with respect to the bond head; and
a contact sensor operable to detect contact forces on different regions of the bond stage; and
a system controller coupled to the bond head, the first actuator, the second actuator, and the contact sensor, the system controller being operable to:
direct the first actuator to move the bond head towards a second movable object disposed on the support surface of the bond stage; and
direct the second actuator to tilt the bond stage about at least one tilt axis in response to the contact sensor detecting an initial contact between the first object and the second object.

10. The die bonding tool of claim 9, wherein the system controller is further operable to:
direct the second actuator to continue tilting the bond stage once the initial contact between the first object and the second object is detected.

11. The die bonding tool of claim 10, wherein the first actuator is directed to continue move the bond head towards the bond stage while the bond stage is tilting.

12. The die bonding tool of claim 9, wherein system controller is further operable to:
direct the second actuator to stop tilting of the bond stage in response to the system controller determining that a contact criterion between the first object and the second object is met.

13. The die bonding tool of claim 9, wherein the second actuator is operable to move vertically.

14. The die bonding tool of claim 9, wherein the second actuator is disposed at a bottom surface of the bond stage.

15. The die bonding tool of claim 9, wherein the contact sensor comprises at least one encoder operable to determine a relative position and/or motion of different regions of the bond stage.

16. The die bonding tool of claim 9, wherein the contact sensor comprises a plurality of force sensors disposed around an outer periphery of the bond stage.

17. A method for bonding a semiconductor die to a target substrate using a die bonding tool, comprising:
positioning a semiconductor die secured to a lower surface of a bond head of the die bonding tool over a top surface of the target substrate, wherein the top surface of the target substrate is not parallel to the lower surface of the bond head;
moving the bond head towards the top surface of the target substrate;
detecting an initial contact between a first region of the semiconductor die and a first region of the target substrate using at least one contact sensor of the die bonding tool; and
tilting the bond stage and the target substrate to bring a second region of the semiconductor die into contact with a second region of the target substrate.

18. The method of claim 17, further comprising:
directing the bond head to continue move towards the bond stage while the bond stage is tilting.

19. The method of claim 18, further comprising:
directing the bond stage to stop tilting when a contact criterion between the semiconductor die and the target substrate is met.

20. The method of claim 17, further comprising:
performing a bonding process to bond the semiconductor die to the target substrate.
